(19) United States
(12) Patent Application Publication
(10) Pub. No.: US 2025/0287509 A1
(43) Pub. Date: Sep. 11, 2025

(54) METHOD FOR MANUFACTURING CERAMIC SUBSTRATE

(71) Applicant: AMOGREENTECH CO., LTD., Gimpo-si, Gyeonggi-do (KR)

(72) Inventor: Jihyung LEE, Gimpo-si (KR)

(73) Assignee: AMOGREENTECH CO., LTD., Gimpo-si, Gyeonggi-do (KR)

(21) Appl. No.: 18/861,482

(22) PCT Filed: Apr. 25, 2023
(86) PCT No.: PCT/KR2023/005588

§ 371 Date: Oct. 29, 2024

(30) Foreign Application Priority Data
Apr. 29, 2022 (KR) 10-2022-0053715

(51) Int. Cl. H05K 3/06; H05K 3/04

(52) U.S. Cl. CPC H05K 3/064; H05K 3/04; H05K 2203/033; H05K 2203/0369; H05K 2203/128

(57) ABSTRACT

The present invention relates to a method for manufacturing a ceramic substrate. Each of upper and lower metal layers respectively bonded to upper and lower surfaces of the ceramic substrate may have a thickness of 0.3 mm to 10 mm, so as to be applicable to a high output power module, and may reduce a chemical etching process time by performing, in advance, a trenching process, which is a mechanical processing scheme, in order to form an electrode pattern on the upper metal layer.

### TECHNICAL FIELD

Embodiments of the present disclosure relate to a method for manufacturing a ceramic substrate, and more particularly, to a method for manufacturing a ceramic substrate in which a pattern can be easily formed on an upper metal layer.

### BACKGROUND ART

In general, an electric vehicle requires an inverter that converts a DC voltage provided from a high-voltage battery into an AC three-phase voltage for driving a motor.

Such an inverter is assembled with a power module for regulating a high voltage of a driving battery to a state suitable for the motor and supplying the regulated voltage. The power module includes a semiconductor chip for converting power, and such a semiconductor chip generates high-temperature heat due to a high-voltage and high-current operation. When such heat continues, there are problems in that the semiconductor chip deteriorates and the performance of the power module deteriorates.

In order to solve such problems, a heat sink is provided on at least one surface of a ceramic or a metal substrate, and the heat dissipation function of the heat sink prevents the semiconductor chip from deteriorating due to heat. The heat sink is made of metal for heat dissipation, but even in the case of such a heat sink made of metal, there is a limit to heat dissipation. When heat exceeding a limit is generated, the cooling efficiency drops sharply, which causes a breakdown. In addition, even in the case of a substrate on which the semiconductor chip is mounted, there is a problem in that bonding characteristics deteriorate due to warping caused by heat.

### DISCLOSURE

### Technical Problem

An object of the present disclosure is to provide a method for manufacturing a ceramic substrate in which upper and lower metal layers having a thickness in a range from 0.3 mm to 10 mm are bonded to a ceramic material so as to have excellent electrical and thermal conductivity and a patterning process of forming an electrode pattern on the upper metal layer is efficiently performed.

### Technical Solution

A method for manufacturing a ceramic substrate according to an embodiment of the present disclosure may include: bonding an upper metal layer to an upper portion of a ceramic material and bonding a lower metal layer to a lower portion of the ceramic material; forming a trench in a thickness direction on a part of an upper portion of the upper metal layer; forming a photoresist pattern that exposes the trench on an upper surface of the upper metal layer; and etching a portion of the upper metal layer corresponding to the trench by using the photoresist pattern as an etching mask.

In the forming of the trench, the trench may be formed through physical processing.

In the forming of the trench, the trench may be formed by removing the part of the upper metal layer by 50% to 90% of a total thickness of the upper metal layer.

The bonding may include: disposing the bonding layer between an upper surface of the ceramic material and a lower surface of the upper metal layer and between a lower surface of the ceramic material and an upper surface of the lower metal layer; and melting the bonding layer to bond the ceramic material, the upper metal layer, and the lower metal layer to one another by brazing.

The method for manufacturing a ceramic substrate according to an embodiment of the present disclosure may further include etching an exposed portion of the bonding layer until the upper surface of the ceramic material is exposed.

In the disposing of the bonding layer, the bonding layer made of a material comprising at least one of Ag, AgCu, and AgCuTi may be disposed by any one of plating, paste application, and foil attachment.

In the forming of the photoresist pattern, a distance between the photoresist patterns disposed on both sides of the trench may be formed longer than a width of the trench.

In the etching, a width by which the upper metal layer is etched may be wider than a width of the trench.

In the forming of the trench, a plurality of trenches may be formed in the upper metal layer at predetermined intervals.

In the forming of the photoresist pattern, the photoresist pattern may expose the plurality of trenches and a part of a surface between the plurality of trenches.

A method for manufacturing a ceramic substrate according to another embodiment of the present disclosure may include: bonding an upper metal layer to an upper portion of a ceramic material and bonding a lower metal layer to a lower portion of the ceramic material; forming a trench in a thickness direction on a part of an upper portion of the upper metal layer; disposing a mask pattern that exposes the trench on an upper surface of the upper metal layer; and etching a portion of the upper metal layer corresponding to the trench by using the mask pattern as an etching mask.

In the forming of the trench, the trench may be formed through physical processing.

In the forming of the trench, the trench may be formed by removing the part of the upper metal layer by 50% to 90% of a total thickness of the upper metal layer.

The bonding may include: disposing the bonding layer between an upper surface of the ceramic material and a lower surface of the upper metal layer and between a lower surface of the ceramic material and an upper surface of the lower metal layer; and melting the bonding layer to bond the ceramic material, the upper metal layer, and the lower metal layer to one another by brazing.

The method for manufacturing a ceramic substrate according to another embodiment of the present disclosure may further include etching an exposed portion of the bonding layer until the upper surface of the ceramic material is exposed.

### Advantageous Effects

The present disclosure can reduce a chemical etching process time by performing a trenching process being a mechanical processing scheme in advance in order to form an electrode pattern on an upper metal layer.

In addition, the present disclosure can save time and cost for forming an electrode pattern on an upper metal layer, thereby not only enabling efficient patterning but also increasing the precision and quality of a pattern.

In addition, the present disclosure can be applied to a power module for high-output power conversion because an upper metal layer is made of any one of Cu, Al, a CuMo alloy, and a CuW alloy and is formed with a thickness of 0.3 mm to 10 mm, so that high voltage and high current can flow through the upper metal layer and the thermal conductivity is excellent.

In addition, the present disclosure can satisfy high heat dissipation conditions required for a power module and suppress warpage because a lower metal layer is made of any one of Cu, Al, a CuMo alloy, and a CuW alloy and is formed with a thickness of 0.3 mm to 10 mm.

### DESCRIPTION OF DRAWINGS

FIG. 1 is a perspective view illustrating a ceramic substrate according to an embodiment of the present invention.

FIG. 2 is a cross-sectional view taken along line A-A′ of FIG. 1.

FIG. 3 is a flowchart illustrating a method for manufacturing a ceramic substrate according to an embodiment of the present invention.

FIG. 4 is a diagram for describing a step of bonding an upper metal layer to an upper portion of a ceramic material of FIG. 3 and a step of bonding a lower metal layer to a lower portion of the ceramic material.

FIG. 5 is a diagram for describing a step of forming a trench of FIG. 3.

FIG. 6 is a diagram for describing a step of forming a photoresist pattern of FIG. 3 and an etching step.

FIG. 7 is a diagram for describing a step of etching a portion of a bonding layer until an upper surface of the ceramic material is exposed and a step of removing a photoresist pattern in a method for manufacturing a ceramic substrate according to an embodiment of the present invention.

FIG. 8 is a diagram for describing a modified example of a photoresist pattern in a method for manufacturing a ceramic substrate according to an embodiment of the present invention.

FIG. 9 is a plan view for describing a modified example in which a plurality of trenches are formed in a step of forming a trench of FIG. 3.

FIG. 10 is a plan view illustrating a state in which a photoresist pattern is formed in FIG. 9.

FIG. 11 is a flowchart showing a method for manufacturing a ceramic substrate according to another embodiment of the present invention.

FIG. 12 is a diagram for describing a step of forming a mask pattern of FIG. 11.

### MODE FOR INVENTION

Hereinafter, preferred embodiments of the present disclosure are described in detail with reference to the accompanying drawings.

Embodiments are provided to more fully explain the present disclosure to a person having ordinary knowledge in the art to which the present disclosure pertains. The following embodiments may be modified in various other forms, and the scope of the present disclosure is not limited to the following embodiments. Rather, these embodiments are provided to make the present disclosure more thorough and complete and to fully convey the spirit of the present disclosure.

Terms used in this specification are used to describe a specific embodiment, and are not intended to limit the present disclosure. Furthermore, in this specification, an expression of the singular number may include an expression of the plural number unless clearly defined otherwise in the context.

In the description of the embodiments, when it is described that each layer (film), area, pattern, or structure is formed “on” or “under” each substrate, layer (film), area, pad, or pattern, this includes both expressions, including that a layer is formed on another layer “directly” or “with a third layer interposed between the two layers (indirectly)”. Furthermore, a criterion for the term “on or under of each layer” is described based on the drawings.

The drawings are merely for enabling the spirit of the present disclosure to be understood, and it should not be interpreted that the scope of the present disclosure is limited by the drawings. Furthermore, in the drawings, a relative thickness or length or a relative size may be enlarged for convenience and the clarity of description.

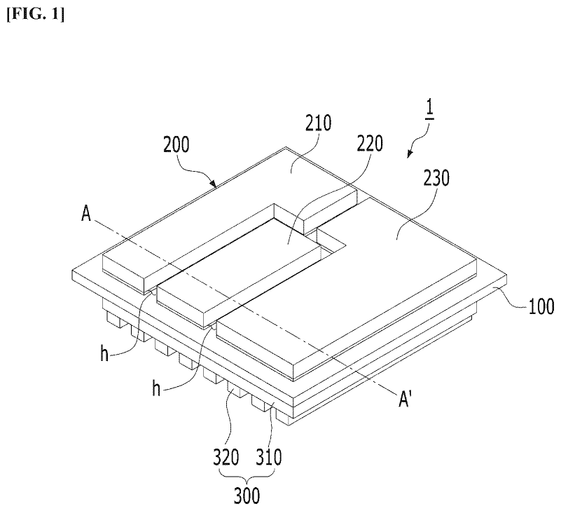

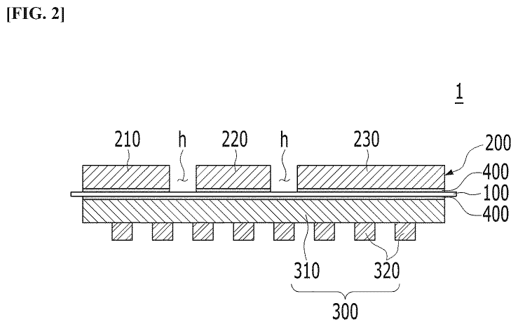

FIG. 1 is a perspective view illustrating a ceramic substrate according to an embodiment of the present invention, and FIG. 2 is a cross-sectional view taken along line A-A′ of FIG. 1.

As illustrated in FIGS. 1 and 2, a ceramic substrate 1 according to an embodiment of the present invention may include a ceramic material 100, an upper metal layer 200 bonded to an upper portion of the ceramic material 100, and a lower metal layer 300 bonded to a lower portion of the ceramic material 100. In the present embodiment, an AMB substrate is described as an example; however, a direct bonding copper (DBC) substrate, a thick printing copper (TPC) substrate, and a DBA (direct brazed aluminum) substrate may also be applied. The AMB substrate is most suitable in terms of durability and heat dissipation efficiency.

The ceramic material 100 may be made of an oxide-based or nitride-based ceramic material. For example, the ceramic material 100 may be any one of alumina (Al₂O₃), AlN, SiN, Si₃N₄, and zirconia toughened alumina (ZTA), but is not limited thereto.

The upper metal layer 200 may be brazed to the upper portion of the ceramic material 100 via a bonding layer 400. The upper metal layer 200 may be made of any one of Cu, a Cu alloy (CuMo etc.), OFC, EPT Cu, and Al. The upper metal layer 200 may have a plurality of electrode patterns 210, 220, and 230 formed so that electrical circuit connections can be made with semiconductor chips (not illustrated) such as Si, LED, VCSEL, SiC, and GaN. The present embodiment illustrates an example in which a first electrode pattern 210, a second electrode pattern 220, and a third electrode pattern 230 are spaced apart from one another with a groove h therebetween; however, the present invention is not limited thereto and various numbers and shapes of electrode patterns may be designed depending on semiconductor chips to be mounted, etc.

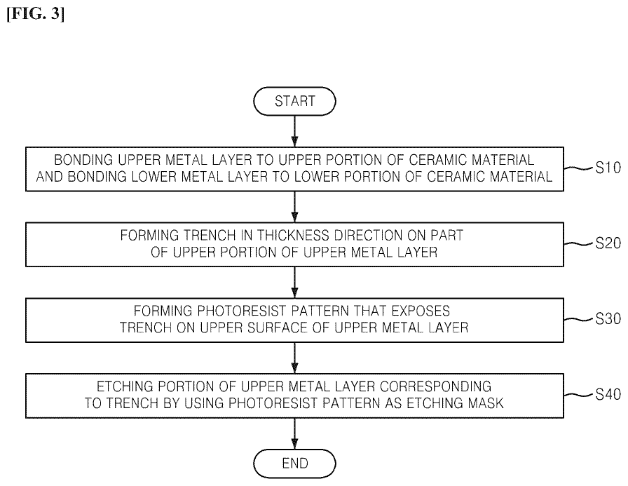

The process for forming the plurality of electrode patterns 210, 220, and 230 on the upper metal layer 200 is described in detail below with reference to FIGS. 3 to 7.

The upper metal layer 200 may be formed to have a thickness of 0.3 mm to 10 mm. In the case of a power module in which high-power power conversion is performed, the upper metal layer 200 circuit-connected to a semiconductor chip needs to have high electrical conductivity and high thermal conductivity for heat dissipation. The ceramic substrate 1 according to the embodiment of the present invention has an advantage in that the upper metal layer 200 has excellent electrical and thermal conductivity because it is made of any one of Cu, Al, and a Cu alloy and has a relatively thick thickness of 0.3 mm to 10 mm and can be applied to a power module for high-output power conversion.

The lower metal layer 300 is brazed to the lower portion of the ceramic material 100 via the bonding layer 400, and may be formed to have a thickness of 1.0 mm or more. The lower metal layer 300 may be made of any one of Cu, Al, a CuMo alloy, and a CuW alloy to increase heat dissipation efficiency. For example, the lower metal layer 300 may be made of any one of Cu, Al, AlSiC, CuMo, CuW, Cu/CuMo/Cu, Cu/Mo/Cu, and Cu/W/Cu, or a composite material thereof. The materials of Cu, Al, AlSiC, CuMo, CuW, Cu/CuMo/Cu, Cu/Mo/Cu, and Cu/W/Cu have excellent thermal conductivity, and the materials of AlSiC, CuMo, CuW, Cu/CuMo/Cu, Cu/Mo/Cu, and Cu/W/Cu have a low thermal expansion coefficient, so that warpage can be minimized when bonded to the ceramic material 100.

The lower metal layer 300 may be provided as a heat sink that operates by either an air-cooling method or a water-cooling method. The air-cooling heat sink may be supplied with air as a coolant. The water-cooling heat sink may be supplied with cooling water, liquid nitrogen, alcohol, or other solvents as a coolant through circulation by pumping force, and heat may be quickly absorbed and released as the flow rate of the coolant is adjusted. The water-cooling heat sink may be any one of a Micro Channel, Pin Fin, Micro Jet, and Slit type. The present embodiment illustrates an example in which the lower metal layer 300 is provided as a slit-type heat sink and includes a flat surface 310 in the shape of a rectangular plate having a predetermined thickness, and a plurality of protrusions 320 arranged at intervals from each other on a lower surface of the flat surface 310. However, the shape of the lower metal layer 300 is not limited thereto. In addition, the protrusions 320 may be provided in various pin shapes such as a cylinder, a polygonal cylinder, a teardrop shape, or a diamond shape, and such shapes may be implemented by mold processing, etching processing, milling processing, or other processing.

The bonding layer 400 may be disposed between the ceramic material 100 and the upper metal layer 200 and between the ceramic material 100 and the lower metal layer 300, and may integrally bond the ceramic material 100 and the upper and lower metal layers 200 and 300 at a brazing temperature. The brazing temperature may be 450° C. or higher.

The bonding layer 400 may be made of an alloy material including at least one of Ag, AgCu, and AgCuTi. Since the material such as Ag, AgCu, and AgCuTi has a thermal conductivity of about 350 W/m·K or higher, the material may facilitate heat transfer between the ceramic material 100 and the upper and lower metal layers 200 and 300, thereby increasing heat dissipation efficiency. In addition, the ceramic material 100 and the upper and lower metal layers 200 and 300 may be airtightly bonded to each other by brazing bonding via the bonding layer 400, and thus may have high bonding strength that can withstand water pressure, hydraulic pressure, etc. and excellent high-temperature reliability. The ceramic material 100 and the upper and lower metal layers 200 and 300 may also be temporarily bonded through thermochemical bonding and then brazed. In such a case, the thermochemical bonding may be a bonding using thermal fusion, adhesive, sticking agent, etc.

FIG. 3 is a flowchart showing a method for manufacturing a ceramic substrate according to an embodiment of the present invention.

As illustrated in FIG. 3, the method for manufacturing a ceramic substrate according to an embodiment of the present invention may include a step S10 of bonding the upper metal layer 200 to the upper portion of the ceramic material 100 and bonding the lower metal layer 300 to the lower portion of the ceramic material 100, a step S20 of forming a trench t in a thickness direction on a part of an upper portion of the upper metal layer 200, a step S30 of forming a photoresist pattern 20 that exposes the trench t on an upper surface of the upper metal layer 200, and a step S40 of etching a portion of the upper metal layer 200 corresponding to the trench t by using the photoresist pattern 20 as an etching mask.

In the step S10 of bonding the upper metal layer 200 to the upper portion of the ceramic material 100 and bonding the lower metal layer 300 to the lower portion of the ceramic material 100, the upper metal layer 200 has excellent electrical and thermal conductivity because it is made of any one of Cu, Al, and a Cu alloy and has a relatively thick thickness of 0.3 mm to 10 mm and can be applied to a power module for high-output power conversion. In addition, the lower metal layer 300 has excellent thermal conductivity because it is made of any one of Cu, Al, a CuMo alloy, and a CuW alloy and can suppress warpage because it is formed with a relatively thick thickness of 1 mm or more in correspondence with the upper metal layer 200.

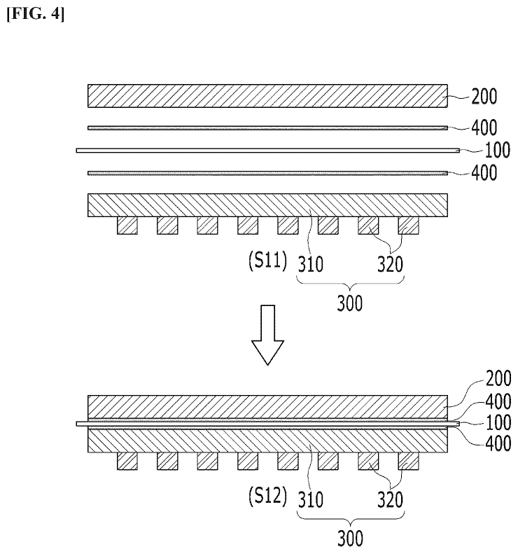

Referring to FIG. 4, the step S10 of bonding the upper metal layer 200 to the upper portion of the ceramic material 100 and bonding the lower metal layer 300 to the lower portion of the ceramic material 100 may include a step S11 of disposing the bonding layer 400 between an upper surface of the ceramic material 100 and a lower surface of the upper metal layer 200 and between a lower surface of the ceramic material 100 and an upper surface of the lower metal layer 300, and a step S12 of melting the bonding layer 400 to bond the ceramic material 100, the upper metal layer 200, and the lower metal layer 300 to one another by brazing.

In the step S11 of disposing the bonding layer 400, the bonding layer 400 made of a material including at least one of Ag, AgCu, and AgCuTi may be disposed by any one of plating, paste application, and foil attachment. The bonding layer 400 may be disposed between the upper surface of the ceramic material 100 and the lower surface of the upper metal layer 200 and between the lower surface of the ceramic material 100 and the upper surface of the lower metal layer 300, and the thickness of the bonding layer 400 may be in a range of about 0.3 μm to about 3.0 μm, but is not limited thereto.

After the step S11 of disposing the bonding layer 400, the step S12 of melting the bonding layer 400 to bond the ceramic material 100, the upper metal layer 200, and the lower metal layer 300 to one another by brazing may be performed. In the brazing bonding step S12, in the state in which the lower metal layer 300, the ceramic material 100, and the upper metal layer 200 are stacked, the bonding layer 400 interposed between the respective layers may be melted at 450° C. or higher, preferably 780° C. to 900° C., so that the ceramic material 100, the upper metal layer 200, and the lower metal layer 300 may be bonded to one another by brazing. In such a case, upper weight or pressure may be applied in order to increase the bonding force.

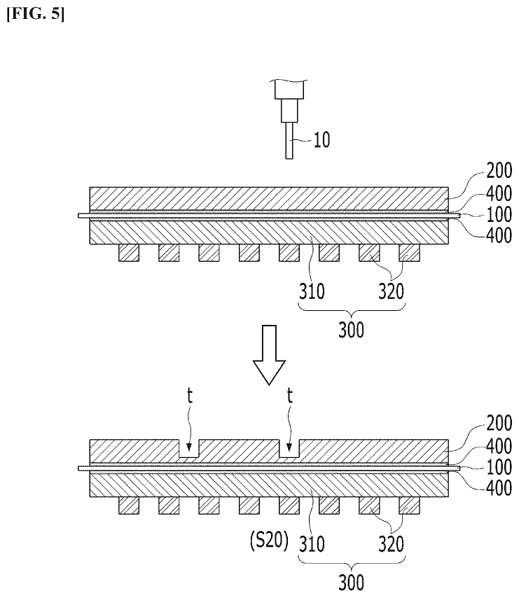

Referring to FIG. 5, in the step S20 of forming the trench t in the thickness direction on the part of the upper portion of the upper metal layer 200, the trench t in the thickness direction may be formed by performing milling being physical processing on the part of the upper portion of the upper metal layer 200. The part of the upper portion of the upper metal layer 200 is cut by a milling tip 10 being a rotating blade, so that the trench t in the thickness direction may be formed. The milling device may be provided to freely form trenches t with various depths and slopes by moving the milling tip 10 according to a designed circuit pattern. The mechanical processing scheme using such a milling tip 10 has the advantage of being able to quickly and precisely form the trench t even though the upper metal layer 200 is formed thick. That is, the circuit pattern can be freely designed according to semiconductor chips, product specifications, etc., and since a fine pattern can be formed, various power modules can be designed and manufactured. Even though a pattern is changed, the pattern change can be corrected by a computer to flexibly respond to the changed pattern. In addition, since the present invention processes the trench t in the state in which the upper metal layer 200 is bonded to the ceramic material 100, an additional process, such as bonding the upper metal layer 200 to the ceramic material 100 in a state where it is separated into a plurality of electrode patterns in advance, is unnecessary, so that productivity can be improved.

In the step S20 of forming the trench t, the trench t may be formed by removing the part of the upper metal layer 200 by 50% to 90% of the total thickness of the upper metal layer 200. For example, when the total thickness of the upper metal layer 200 is 10 mm, the trench t may be formed by removing the part of the upper portion of the upper metal layer 200 by a thickness of 7 mm. In addition, when the total thickness of the upper metal layer 200 is 7 mm, the trench t may be formed by removing the part of the upper portion of the upper metal layer 200 by a thickness of 6 mm. On the other hand, when the total thickness of the upper metal layer 200 is 3 mm, the width of the trench t may be 3.2 mm or 3.5 mm, but is not limited thereto.

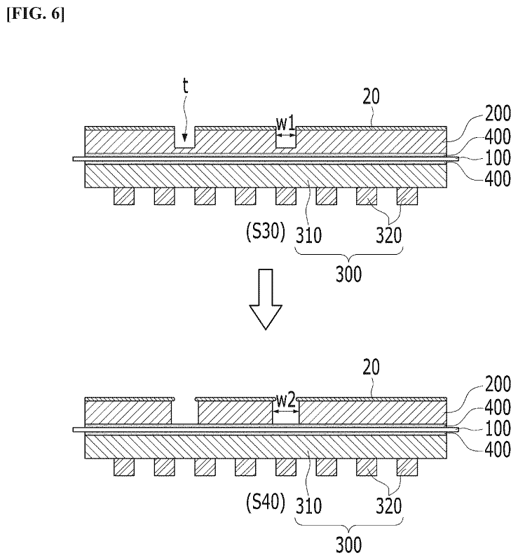

Referring to FIG. 6, in the step S30 of forming the photoresist pattern 20 that exposes the trench t on the upper surface of the upper metal layer 200, the photoresist pattern 20 may be formed by performing a photolithography process on the upper metal layer 200. Although not illustrated in detail, the photolithography process may form the photoresist pattern 20 by forming a photoresist layer and then performing an exposure and development process on the photoresist layer. The photoresist pattern 20 may be formed to expose the trench t in order to etch a portion of the upper metal layer 200 corresponding to the trench t.

After the step S30 of forming the photoresist pattern 20, the step S40 of etching the portion of the upper metal layer 200 corresponding to the trench t by using the photoresist pattern 20 as the etching mask may be performed. As illustrated in FIG. 6, in the etching step S40, a width w2 by which the upper metal layer 200 is etched may be wider than a width w1 of the trench t, and may be wider than the distance between the photoresist patterns 20 as illustrated in the drawing depending on an etchant.

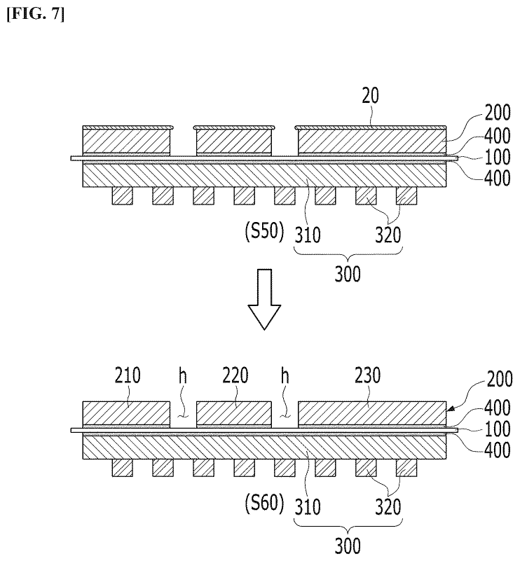

Referring to FIG. 7, the method for manufacturing a ceramic substrate according to an embodiment of the present invention may further include, after the etching step S40, a step S50 of etching an exposed portion of the bonding layer 400 until the upper surface of the ceramic material 100 is exposed. The step S50 of etching until the upper surface of the ceramic material 100 is exposed may include a step of etching a material formed by a reaction between the ceramic material 100 and the bonding layer 400. For example, when the ceramic material 100 is a nitride-based material such as AlN or Si₃N₄, since TiN may be formed by reacting with Ti of the bonding layer 400, a step of etching TiN may be included.

After the step S50 of etching until the upper surface of the ceramic material 100 is exposed, a step S60 of removing the photoresist pattern 20 through dry or wet etching is performed, thereby manufacturing the ceramic substrate 1 on which the plurality of electrode patterns 210, 220, and 230 are formed.

In this way, by etching the portion of the upper metal layer 200 and the portion of the bonding layer 400 corresponding to the trench t until the upper surface of the ceramic material 100 is exposed, the plurality of electrode patterns 210, 220, and 230 spaced apart from one another with the groove h among them may be formed. Since the plurality of electrode patterns 210, 220, and 230 are electrically isolated according to a designed circuit pattern, no short circuit phenomenon occurs when a semiconductor chip is connected to a circuit.

When the upper metal layer 200 is formed with a relatively thick thickness of 0.3 mm to 10 mm, forming an electrode pattern only by an etching process has the problem that the etching time takes too long and the precision of the pattern is not good. On the other hand, the method for manufacturing a ceramic substrate of the present invention has the effect of reducing the chemical etching process time by performing a trenching process being a mechanical processing scheme in advance in order to form the plurality of electrode patterns 210, 220, and 230. The trenching process may form the trench t in the thickness direction by removing a portion of the upper metal layer 200 by 50% to 90% of the total thickness of the upper metal layer 200. Accordingly, even though the upper metal layer 200 has a very thick thickness of about 10 mm, when the trench t having a thickness of 7 mm is formed in advance, the thickness of the upper metal layer 200 to be etched is reduced to 3 mm, so that the time required for etching can be drastically reduced. In this way, the method for manufacturing a ceramic substrate of the present invention has the advantage of not only enabling efficient patterning but also improving the precision and quality of a pattern.

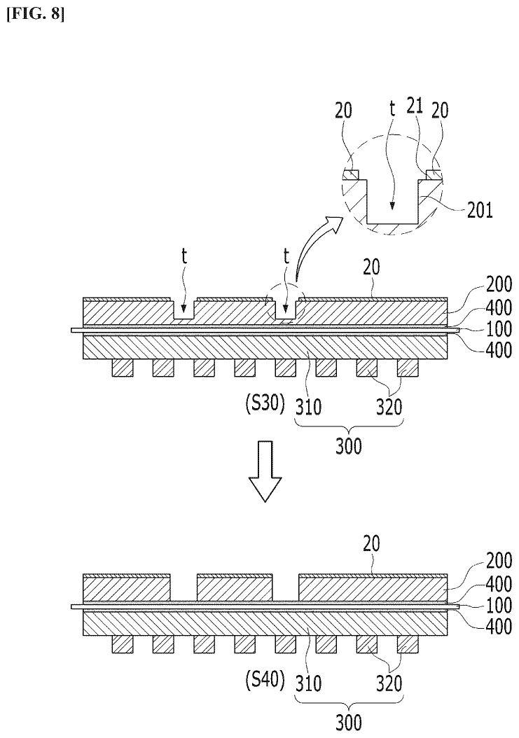

FIG. 8 is a diagram for describing a modified example of a photoresist pattern in the method for manufacturing a ceramic substrate according to an embodiment of the present invention.

Referring to FIG. 8, in the step S30 of forming the photoresist pattern 20, the distance between the photoresist patterns 20 disposed on both sides of the trench t may be formed longer than the width of the trench t. In this way, when the photoresist pattern 20 is formed, the width by which the upper metal layer 200 is etched in the etching step S40 may be the same as or almost similar to the distance between the photoresist patterns 20.

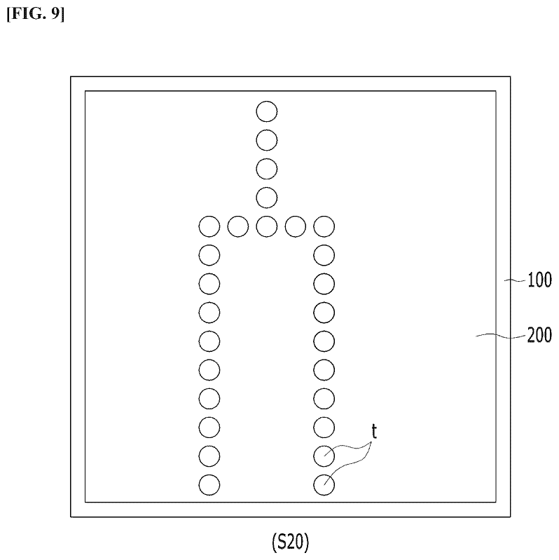

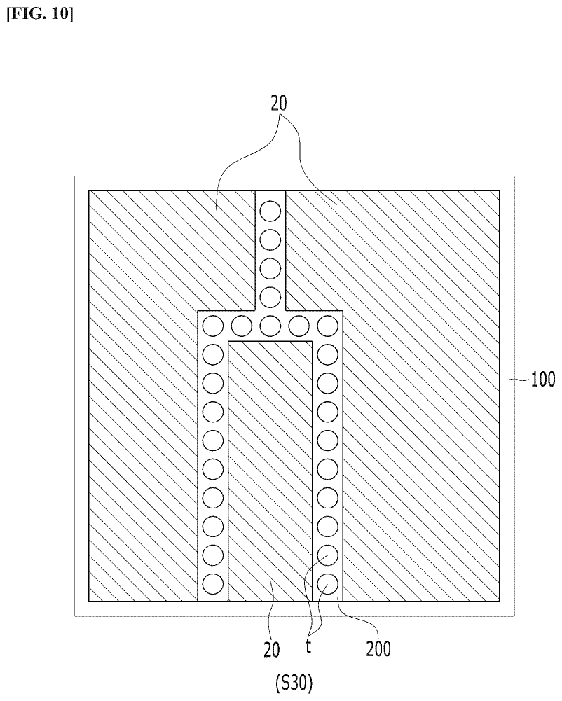

FIG. 9 is a plan view for describing a modified example in which a plurality of trenches are formed in the step of forming a trench of FIG. 3, and FIG. 10 is a plan view illustrating a state in which a photoresist pattern is formed in FIG. 9.

Referring to FIG. 9, in the step S20 of forming the trench t, a plurality of trenches t may be formed in the upper metal layer 200 at predetermined intervals. In the step S20 of forming the trench t, a trench t that is continuously connected be formed, or a plurality of trenches t arranged at predetermined intervals as illustrated in FIG. 9 may be formed. The depth and interval of each of the plurality of trenches t may be formed in various ways according to a designed circuit pattern.

In this way, when the plurality of trenches t are formed on the upper metal layer 200 at predetermined intervals, in the step S30 of forming the photoresist pattern 20, the photoresist pattern 20 may expose the plurality of trenches t and a part of a surface between the plurality of trenches t. In this way, as the photoresist pattern 20 is formed, an area including the plurality of trenches t may be etched in the etching step S40. After the etching step S40, the step S50 of etching the exposed portion of the bonding layer 400 until the upper surface of the ceramic material 100 is exposed and the step S60 of removing the photoresist pattern 20 through dry or wet etching are performed as in the embodiment illustrated in FIG. 7, so that the ceramic substrate 1 on which the plurality of electrode patterns 210, 220, and 230 are formed can be manufactured.

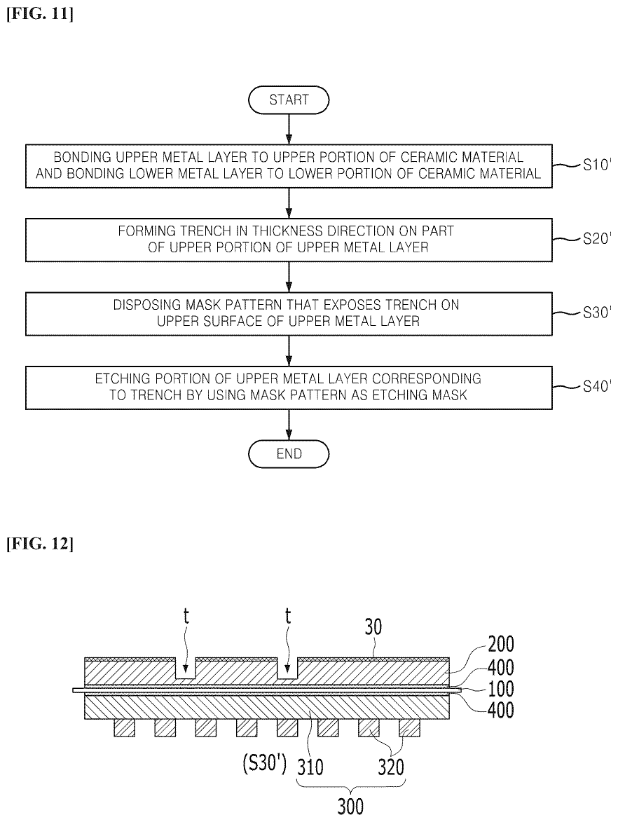

A method for manufacturing a ceramic substrate according to another embodiment of the present invention is described below with reference to FIGS. 11 and 12. For convenience of explanation, components that are identical or corresponding to those illustrated in the embodiment illustrated in FIGS. 3 to 7 are given the same reference numerals, and redundant descriptions thereof are omitted.

FIG. 11 is a flowchart showing a method for manufacturing a ceramic substrate according to another embodiment of the present invention, and FIG. 12 is a diagram for describing a step of forming a mask pattern of FIG. 11.

As illustrated in FIG. 11, the method for manufacturing a ceramic substrate according to another embodiment of the present invention may include a step S10′ of bonding the upper metal layer 200 to the upper portion of the ceramic material 100 and bonding the lower metal layer 300 to the lower portion of the ceramic material 100, a step S20′ of forming the trench t in the thickness direction on the part of the upper portion of the upper metal layer 200, a step S30′ of forming a mask pattern 30 that exposes the trench t on the upper surface of the upper metal layer 200, and a step S40′ of etching the portion of the upper metal layer 200 corresponding to the trench t by using the mask pattern 30 as an etching mask.

As illustrated in FIG. 12, in the method for manufacturing a ceramic substrate according to another embodiment of the present invention, the step S10′ of bonding the upper metal layer 200 to the upper portion of the ceramic material 100 and bonding the lower metal layer 300 to the lower portion of the ceramic material 100 and the step S20′ of forming the trench t in the thickness direction on the part of the upper portion of the upper metal layer 200 may be performed in the same manner as in an embodiment. In the method for manufacturing a ceramic substrate according to another embodiment of the present invention, after the step S20′ of forming the trench t, the step S30′ of forming the mask pattern 30 that exposes the trench t on the upper surface of the upper metal layer 200 may be performed. Subsequently, the step S40′ of etching the portion of the upper metal layer 200 corresponding to the trench t by using the mask pattern 30 as the etching mask may be performed. In this way, since the method for manufacturing a ceramic substrate according to another embodiment of the present invention forms the mask pattern 30 on the upper surface of the upper metal layer 200, unlike an embodiment of forming the photoresist pattern 20, the method can reduce additional processes such as a photolithography process and the ceramic substrate can be reused.

The methods for manufacturing a ceramic substrate according to the embodiments of the present invention described above have the effect of reducing the chemical etching process time by performing a trenching process being a mechanical processing scheme in advance in order to form a plurality of electrode patterns. In addition, the methods for manufacturing a ceramic substrate of the present invention has the advantage of not only enabling efficient patterning but also increasing the precision and quality of the pattern.

The ceramic substrate of the present invention described above can be applied to various devices requiring high output and high heat dissipation characteristics in addition to single-sided or double-sided cooling power modules.

The above description is merely intended to illustratively describe the technical spirit of the present disclosure, and various changes and modifications can be made by those skilled in the art to which the present disclosure pertains without departing from the essential features of the present disclosure. Therefore, the embodiments disclosed in the present disclosure are not intended to limit the technical spirit of the present disclosure, but are intended to describe the present disclosure. The scope of the technical spirit of the present disclosure is not limited by these embodiments. The scope of the present disclosure should be interpreted by the accompanying claims and all technical spirits falling within the equivalent scope thereto should be interpreted as being included in the scope of the present disclosure.

1. A method for manufacturing a ceramic substrate, comprising:
bonding an upper metal layer to an upper portion of a ceramic material and bonding a lower metal layer to a lower portion of the ceramic material;
forming a trench in a thickness direction on a part of an upper portion of the upper metal layer;
forming a photoresist pattern that exposes the trench on an upper surface of the upper metal layer; and
etching a portion of the upper metal layer corresponding to the trench by using the photoresist pattern as an etching mask.

2. The method for manufacturing a ceramic substrate of claim 1, wherein in the forming of the trench, the trench is formed through physical processing.

3. The method for manufacturing a ceramic substrate of claim 1, wherein in the forming of the trench, the trench is formed by removing the part of the upper metal layer by 50% to 90% of a total thickness of the upper metal layer.

4. The method for manufacturing a ceramic substrate of claim 1, wherein the bonding comprises:
disposing the bonding layer between an upper surface of the ceramic material and a lower surface of the upper metal layer and between a lower surface of the ceramic material and an upper surface of the lower metal layer; and
melting the bonding layer to bond the ceramic material, the upper metal layer, and the lower metal layer to one another by brazing.

5. The method for manufacturing a ceramic substrate of claim 4, further comprising:
etching an exposed portion of the bonding layer until the upper surface of the ceramic material is exposed.

6. The method for manufacturing a ceramic substrate of claim 4, wherein in the disposing of the bonding layer, the bonding layer made of a material comprising at least one of Ag, AgCu, and AgCuTi is disposed by any one of plating, paste application, and foil attachment.

7. The method for manufacturing a ceramic substrate of claim 1, wherein in the forming of the photoresist pattern, a distance between the photoresist patterns disposed on both sides of the trench is formed longer than a width of the trench.

8. The method for manufacturing a ceramic substrate of claim 1, wherein in the etching, a width by which the upper metal layer is etched is wider than a width of the trench.

9. The method for manufacturing a ceramic substrate of claim 1, wherein in the forming of the trench, a plurality of trenches are formed in the upper metal layer at predetermined intervals.

10. The method for manufacturing a ceramic substrate of claim 9, wherein in the forming of the photoresist pattern, the photoresist pattern exposes the plurality of trenches and a part of a surface between the plurality of trenches.

11. A method for manufacturing a ceramic substrate, comprising:
bonding an upper metal layer to an upper portion of a ceramic material and bonding a lower metal layer to a lower portion of the ceramic material;
forming a trench in a thickness direction on a part of an upper portion of the upper metal layer;
disposing a mask pattern that exposes the trench on an upper surface of the upper metal layer; and
etching a portion of the upper metal layer corresponding to the trench by using the mask pattern as an etching mask.

12. The method for manufacturing a ceramic substrate of claim 11, wherein in the forming of the trench, the trench is formed through physical processing.

13. The method for manufacturing a ceramic substrate of claim 11, wherein in the forming of the trench, the trench is formed by removing the part of the upper metal layer by 50% to 90% of a total thickness of the upper metal layer.

14. The method for manufacturing a ceramic substrate of claim 11, wherein the bonding comprises:
disposing the bonding layer between an upper surface of the ceramic material and a lower surface of the upper metal layer and between a lower surface of the ceramic material and an upper surface of the lower metal layer; and
melting the bonding layer to bond the ceramic material, the upper metal layer, and the lower metal layer to one another by brazing.

15. The method for manufacturing a ceramic substrate of claim 14, further comprising:
etching an exposed portion of the bonding layer until the upper surface of the ceramic material is exposed.
